(19) United States
(12) Patent Application Publication
(10) Pub. No.: US 2009/0250248 A1
(43) Pub. Date: Oct. 8, 2009

(54) Support substrate structure for supporting electronic component thereon and method for fabricating the same

(75) Inventors: Ming-Chi Kan, Rende Township (TW); Shao-Chung Hu, Sindian City (TW)

Correspondence Address: BACON & THOMAS, PLLC, 625 SLATERS LANE, FOURTH FLOOR, ALEXANDRIA, VA, 22314-1176, US

(73) Assignee: Kinik Company, Taipei (TW)

(21) Appl. No.: 12/219,708

(22) Filed: Jul. 28, 2008

(30) Foreign Application Priority Data
Apr. 3, 2008 (TW) 097112351

(51) Int. Cl. H05K 3/44; H05K 1/05

(52) U.S. Cl. 174/252; 29/846

(57) ABSTRACT

A support substrate structure for supporting an electronic component thereon comprises a thermal conductive substrate, a first ceramic layer, an insulating thermal conductive layer and a conductive pattern. The thermal conductive substrate has an upper surface and a lower surface; the first ceramic layer is disposed on the upper surface of the thermal conductive substrate; the insulating thermal conductive layer is disposed on the first ceramic layer; and the conductive pattern is formed on a surface of the insulating thermal conductive layer. The present invention also discloses a method for fabricating the aforementioned support substrate structure.

### BACKGROUND OF THE INVENTION

1. Field of the Invention

The present invention relates to a support substrate structure for supporting an electronic component thereon and a method for fabricating the same, more particularly, to a support substrate structure that uses diamond-like carbon to present high thermal conductivity and a method for fabricating the same.

2. Description of Related Art

As the electronics industry develops rapidly, research moves towards electronic products with multifunction and high performance. Currently, the size of circuit boards in electronic products is reduced to meet the requirements for more compact and lightweight electronic products and to develop various portable electronic products. However, the reduced size of circuit boards makes heat dissipation more difficult.

A commonly-used light emitting diode device (LED) can be widely applied in many electronic devices, such as backlight sources of display devices, mini projectors and light sources due to its high brightness. However, in an LED, 80% input power will be converted to heat. If the heat cannot be suitably dissipated, the junction temperature of the LED will increase which results in the decreasing of the brightness and the lifetime thereof. Therefore, it is necessary to improve heat dissipation in manufacturing circuit boards.

As shown in FIG. 1, a support substrate structure with a diamond layer is disclosed in U.S. Pat. No. 5,907,189. In the support substrate, a diamond layer 802 is formed on the surface of a ceramic substrate 800. In addition, a semiconductor component 810 is disposed on the diamond layer 802 via an adhesive material 812 and electrically connects to the ceramic layer 800 via solder wires 806 and through holes 808 in the diamond layer 802. However, in the conventional semiconductor package structure, poor heat dissipation is still a big problem because a ceramic substrate is used as a support substrate for supporting a semiconductor component. Thereby, if the heat generated in long-term operation cannot be efficiently dissipated, the lifetime and performance of the semiconductor component will be badly influenced.

Therefore, it is an important issue to provide a support substrate that can improve heat dissipation.

### SUMMARY OF THE INVENTION

The object of the present invention is to provide a support substrate structure for supporting an electronic component thereon and a method for fabricating the same to efficiently dissipate heat generated from the electronic component, so that the lifetime and performance of the electronic component is improved.

To achieve the aforementioned object or other objects, the present invention provides a support substrate structure, comprising a thermal conductive substrate, a first ceramic layer, an insulating thermal conductive layer and a conductive pattern. The thermal conductive substrate has an upper surface and a lower surface. Herein, the first ceramic layer is disposed on the upper surface; the insulating thermal conductive layer is disposed on the first ceramic layer; and the conductive pattern is formed on the surface of the insulating thermal conductive layer.

According to the support substrate structure of a preferable embodiment in the present invention, the material of the thermal conductive substrate can be a metal or a semiconductor, such as one of aluminum, copper, germanium and germanium arsenide.

The support substrate structure of a preferable embodiment in the present invention can further comprise an adhesive layer formed on the conductive pattern. Herein, the material of the adhesive layer can be nickel, gold, tin, tin alloy or a combination thereof. In addition, the electronic component electrically connects to the conductive pattern via the adhesive layer, and the electronic component can be a chip or a semiconductor component.

The support substrate structure of a preferable embodiment in the present invention can further comprise a second ceramic layer formed on the lower surface of the thermal conductive substrate. Herein, the material of the first ceramic layer and the second ceramic layer can be an oxide, bromide, carbide or a combination thereof.

The support substrate structure of a preferable embodiment in the present invention can further comprise a solder layer formed over the second ceramic layer, and a heat dissipation component can be disposed on the solder layer.

The support substrate structure of a preferable embodiment in the present invention can further comprise a metal middle layer disposed between the solder layer and the second ceramic layer. Herein, the material of the metal middle layer can be chromium, copper, nickel, gold, silver or alloy thereof.

According to the support substrate structure of a preferable embodiment in the present invention, the insulating thermal conductive layer can be a diamond-like carbon film or a diamond film. Herein, the diamond-like carbon film has a dopant, such as fluorine, silicon, nitrogen, boron or a mixture thereof. In addition, the amount of the fluorine or the silicon in the diamond-like carbon film can be 1-40 atom %. Preferably, the amount of the fluorine or the silicon in the diamond-like carbon film is 5-20 atom %. Furthermore, the amount of the nitrogen or the boron in the diamond-like carbon film can be 1-20 atom %. Preferably, the amount of the nitrogen or the boron in the diamond-like carbon film is 5-10 atom %.

According to the support substrate structure of a preferable embodiment in the present invention, the thickness of the insulating thermal conductive layer can be in a range of 0.1 to 30 μm.

The present invention further provides a method for fabricating the aforementioned support substrate structure, comprising: providing a thermal conductive substrate having an upper surface and a lower surface; forming a first ceramic layer on the upper surface of the thermal conductive substrate; forming an insulating thermal layer on the first ceramic layer; forming a conductive layer on the insulating thermal conductive layer; and removing a part of the conductive layer to form a conductive pattern on the insulating thermal conductive layer.

According to the method for fabricating a support substrate structure of a preferable embodiment in the present invention, the material of the thermal conductive substrate can be a metal or a semiconductor, such as one of aluminum, copper, germanium and germanium arsenide.

The method for fabricating a support substrate structure of a preferable embodiment in the present invention can further comprise a step for forming a second ceramic layer on the lower surface of the thermal conductive substrate. Herein, the method for forming the first ceramic layer and the second ceramic layer can be an anodizing process or a thermal treatment process.

The method for fabricating a support substrate structure of a preferable embodiment in the present invention can further comprise a step for forming a solder layer over the second ceramic layer.

The method for fabricating a support substrate structure of a preferable embodiment in the present invention can further comprise a step for forming a metal middle layer between the solder layer and the second ceramic layer.

The method for fabricating a support substrate structure of a preferable embodiment in the present invention can further comprise a step for providing a heat dissipation component on the solder layer. Herein, the heat dissipation component connects to the second ceramic layer via the solder layer.

According to the method for fabricating a support substrate structure of a preferable embodiment in the present invention, the insulating thermal conductive layer can be a diamond-like carbon film or a diamond film. Herein, the diamond-like carbon film has a dopant, such as fluorine, silicon, nitrogen, boron or a mixture thereof. In addition, the amount of the fluorine or the silicon in the diamond-like carbon film can be 1-40 atom %. Preferably, the amount of the fluorine or the silicon in the diamond-like carbon film is 5-20 atom %. Furthermore, the amount of the nitrogen or the boron in the diamond-like carbon film can be 1-20 atom %. Preferably, the amount of the nitrogen or the boron in the diamond-like carbon film is 5-10 atom %.

According to the method for fabricating a support substrate structure of a preferable embodiment in the present invention, the method for forming the insulating thermal conductive layer can be chemical vapor deposition. Herein, the thickness of the insulating thermal conductive layer can be in a range of 0.1 to 30 μm.

According to the method for fabricating a support substrate structure of a preferable embodiment in the present invention, the method for forming the conductive layer can be sputtering, electroplating or electroless plating. Herein, the thickness of the conductive layer can be in a range of 0.1 to 100 μm, and the material of the conductive layer can be copper, silver, gold or chromium.

The method for fabricating a support substrate structure of a preferable embodiment in the present invention can further comprise a step for providing an adhesive layer on the conductive pattern. Herein, an electronic component can be further provided on the conductive pattern and electrically connects to the conductive pattern via the adhesive layer. The electronic component comprises a chip or a semiconductor component.

Accordingly, in the support substrate structure and the method for fabricating the same provided by the present invention, a ceramic layer and an insulating thermal conductive layer are formed over a thermal conductive substrate, so that the heat generated from the electronic component can be efficiently dissipated. Thereby, the performance and lifetime of the electronic component can be improved.

Other objects, advantages, and novel features of the invention will become more apparent from the following detailed description when taken in conjunction with the accompanying drawings.

### BRIEF DESCRIPTION OF THE DRAWINGS

FIG. 1 is a cross-sectional view of a conventional support substrate structure with a diamond layer;

FIG. 2 is a cross-sectional view of a support substrate structure according to an embodiment of the present invention;

FIGS. 3A to 3E show a flow chart for fabricating a support substrate structure as shown in FIG. 2;

FIG. 3F is a cross-sectional view of a support substrate structure with an electronic component is supported thereon according to an embodiment of the present invention;

FIG. 4 is a cross-sectional view of a support substrate structure according to another embodiment of the present invention; and

FIG. 5 is a cross-sectional view of a support substrate structure according to yet another embodiment of the present invention, where the support substrate structure has a heat dissipation component and is used to support an electronic component.

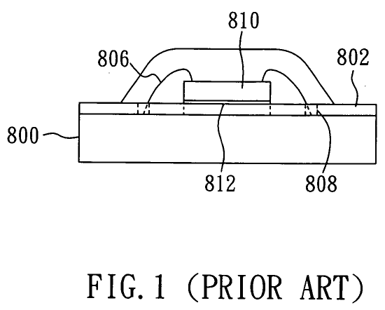

### DETAILED DESCRIPTION OF THE PREFERRED EMBODIMENT

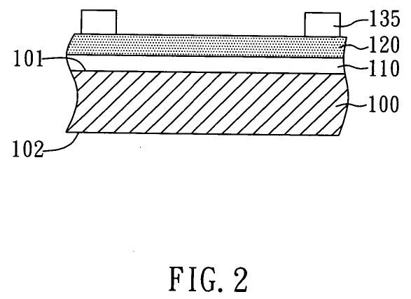

With reference to FIG. 2, there is shown a cross-sectional view of a support substrate structure according to an embodiment of the present invention. The support substrate structure of the present invention comprises a thermal conductive substrate 100, a first ceramic layer 110 and an insulating thermal conductive layer 120. The thermal conductive substrate 100 has an upper surface 101 and a lower surface 102. The first ceramic layer 110 is disposed on the upper surface 101 of the thermal conductive substrate 100, and the insulating thermal conductive layer 120 is disposed on the first ceramic layer 110. In addition, a conductive pattern 135 is disposed on the surface of the insulating thermal conductive layer 120 for electrical connection to other electronic components.

In the present embodiment, the thermal conductive substrate 100 is a metal substrate or a semiconductor substrate. It should be noted that any metal or semiconductor material that has the efficiency for heat dissipation can be used as the material of the thermal conductive substrate. Thereby, the material of the thermal conductive substrate is not limited to the materials mentioned here. In the present embodiment, the metal material includes a metal or an alloy consisting of two or more metals, such as aluminum, copper, an alloy thereof or a compound thereof. The semiconductor material is, for example but not limited to, germanium or germanium arsenide. In addition, the material of the first ceramic layer 110 on the thermal conductive substrate 100 includes any conventional ceramic material, such as oxides, bromides, carbides or a combination thereof.

In the present embodiment, the insulating thermal conductive layer 120 includes a diamond-like carbon film or a diamond film. If necessary, the diamond-like carbon film can be doped with elements as dopants, such as fluorine, silicon, nitrogen or boron, to reduce intrinsic stress in the insulating thermal conductive layer 120 and enhance the adhesion between the insulating thermal conductive layer 120 and the first ceramic layer 110. The amount of dopants (such as fluorine, silicon, nitrogen or boron) in the diamond-like carbon film (used as the insulating thermal conductive layer 120) is not limited as long as the amount will not cause semiconductor effect. The amount of the fluorine or the silicon in the diamond-like carbon film can be 1-40 atom %. Preferably, the amount of the fluorine or the silicon in the diamond-like carbon film is 5-20 atom %. The amount of the nitrogen or the boron in the diamond-like carbon film can be 1-20 atom %. Preferably, the amount of the nitrogen or the boron in the diamond-like carbon film is 5-10 atom %.

In addition, in the present embodiment, the conductive pattern 135 on the insulating thermal conductive layer 120 is used for the electrical connection to other electronic components (not shown in the figures). For example, the conductive pattern can connect to an electronic component via wires. The material of the conductive pattern 135 includes any conductive material, such as chromium, copper, nickel or gold.

In the present invention, a ceramic layer and an insulating thermal conductive layer are formed over a thermal conductive substrate. Thereby, in comparison to a conventional support substrate, the heat generated from an electronic component can further be efficiently dissipated via the ceramic layer and the insulating thermal conductive layer in addition to the thermal conductive substrate.

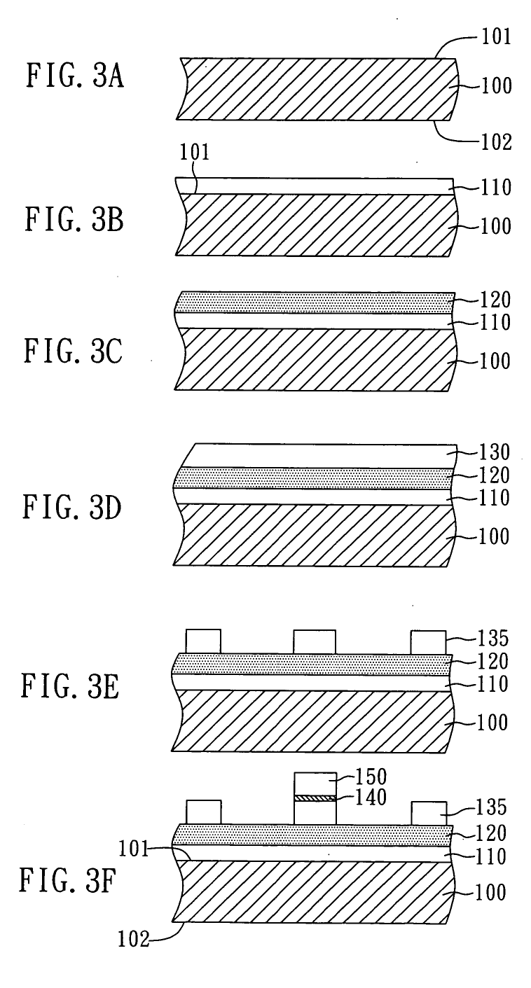

FIGS. 3A to 3E show a flow chart for fabricating the support substrate structure as shown in FIG. 2. With reference to FIG. 3A, a thermal conductive substrate 100 having an upper surface 101 and a lower surface 102 is first provided. Then, as shown in FIG. 3B, a first ceramic layer 110 is formed on the upper surface 101 of the thermal conductive substrate 100. It is noted that the method for forming the first ceramic layer 110 depends on the material of the thermal conductive substrate 100. In the present embodiment, if the thermal conductive substrate 100 is a metal substrate, the first ceramic layer 110 can be formed by an anodizing process. If the thermal conductive substrate 100 is a semiconductor substrate, the first ceramic layer 110 can be formed by a thermal treatment process.

Subsequently, as shown in FIG. 3C, an insulating thermal conductive layer 120 is formed on the first ceramic layer 110. The method for forming the insulating thermal conductive layer 120 is chemical vapor deposition. Herein, the chemical vapor deposition can be performed through any various process based on a main principle. The exemplary chemical vapor deposition includes hot-filament chemical vapor deposition, plasma-enhanced chemical vapor deposition (PECVD), microwave plasma chemical vapor deposition (MPCVD), or other similar methods. In the present embodiment, preferably, the insulating thermal conductive layer 120 is formed on the first ceramic layer 110 by plasma-enhanced chemical vapor deposition at a temperature of 200° C. or less. The thickness of the insulating thermal conductive layer 120 is not limited. Preferably, the thickness of the insulating thermal conductive layer 120 is in a range of 0.1 to 30 μm. In the present embodiment, the thickness of the insulating thermal conductive layer 120 is in a range of about 2 to 3 μm.

With reference to FIG. 3D, a conductive layer 130 is formed on the insulating thermal conductive layer 120 after the formation of the insulating thermal conductive layer 120. The method for forming the conductive layer 130 is, for example, sputtering copper or chromium as a metal layer on the insulating thermal conductive layer 120, thickening the metal layer by electroplating, and finally modifying the surface of the metal layer by electroless plating to form the conductive layer 130. The thickness of the conductive layer 130 is not limited and depends on the density of current applied from the electronic component (not shown in the figures). Preferably, the thickness of the conductive layer 130 is in a range of 0.1 to 100 μm. In the present embodiment, the thickness of the conductive layer 130 is in a range of 20 to 40 μm.

Finally, as shown in FIG. 3E, a part of the conductive layer 130 is removed to form a conductive pattern 135 on the insulating thermal conductive layer 120. The process for removing a part of the conductive layer 130 can be performed by etching.

It is noted that, the support substrate structure of the present invention is used to support an electronic component. As shown in FIG. 3F, an electronic component 150 is disposed on the support substrate structure via an adhesive layer 140. More specifically, an adhesive layer 140 is formed on the conductive pattern 135 of the support substrate structure, and the electronic component 150 is disposed on the support substrate structure via the adhesive layer 140. The electronic component includes a chip or a semiconductor component, such as a light emitting diode.

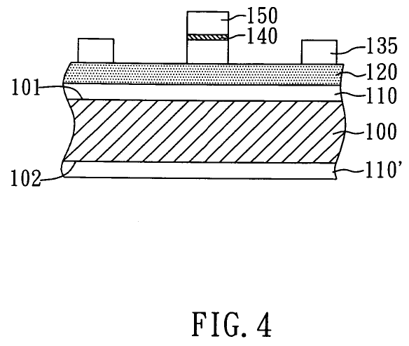

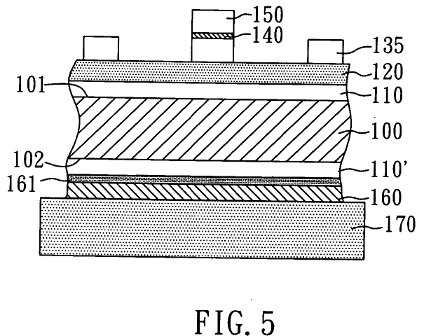

With reference to FIG. 4, there is shown a cross-sectional view of a support substrate structure of another embodiment according to the present invention. In comparison to the support substrate structure and the method for fabricating the same illustrated in the aforementioned embodiment, the support substrate structure of the present embodiment further comprises a second ceramic layer 110′ formed on the lower surface 102 of the thermal conductive substrate. Herein, the material of the second ceramic layer 110′ is the same as the aforementioned one. In addition, the second ceramic layer 110′ is formed in the same manner as the aforementioned one. In yet another embodiment, as shown in FIG. 5, the support substrate structure of the present invention further comprises a heat dissipation component 170. Herein, the heat dissipation component 170 connects to the second ceramic layer 110′ via a solder layer 160. The material of the solder layer 160 is tin or tin alloy. In addition, in the present embodiment, a metal middle layer 161 is further formed between the second ceramic layer 110′ and the solder layer 160 to enhance the adhesion between the second ceramic layer 110′ and the solder layer 160. The material of the metal middle layer 161 is, for example, chromium, copper, nickel, gold, silver or alloy thereof.

Accordingly, the support substrate structure of the present invention comprises a ceramic layer and an insulating thermal conductive layer, and the substrate used in the support substrate structure of the present invention can present the efficiency for thermal conduction. In addition, the support substrate structure of the present invention can further comprise a heat dissipation component. Thereby, the heat generated from an electronic component or an electronic circuit on the support substrate structure can be efficiently dissipated through multiple paths, such as the thermal conductive substrate, the ceramic layer, the insulating thermal conductive layer and the heat dissipation component. Accordingly, the support substrate structure of the present invention can present excellent heat dissipation, so that the stability and the lifetime of the electronic component are significantly enhanced.

Although the present invention has been explained in relation to its preferred embodiment, it is to be understood that many other possible modifications and variations can be made without departing from the scope of the invention as hereinafter claimed.

What is claimed is:

1. A support substrate structure for supporting an electronic component thereon, comprising:
a thermal conductive substrate having an upper surface and a lower surface;
a first ceramic layer disposed on the upper surface of the thermal conductive substrate;
an insulating thermal conductive layer disposed on the first ceramic layer; and
a conductive pattern formed on a surface of the insulating thermal conductive layer.

2. The support substrate structure for supporting an electronic component thereon as claimed in claim 1, wherein the material of the thermal conductive substrate is a metal or a semiconductor, comprising one of aluminum, copper, germanium and germanium arsenide.

3. The support substrate structure for supporting an electronic component thereon as claimed in claim 1, further comprising an adhesive layer formed on the conductive pattern, wherein the electronic component electrically connects to the conductive pattern via the adhesive layer, and the electronic component is a chip or a semiconductor component.

4. The support substrate structure for supporting an electronic component thereon as claimed in claim 3, wherein the material of the adhesive layer is nickel, gold, tin, tin alloy or a combination thereof.

5. The support substrate structure for supporting an electronic component thereon as claimed in claim 1, further comprising a second ceramic layer on the lower surface of the thermal conductive substrate.

6. The support substrate structure for supporting an electronic component thereon as claimed in claim 5, wherein the material of the first ceramic layer and the second ceramic layer is an oxide, bromide, carbide or a combination thereof.

7. The support substrate structure for supporting an electronic component thereon as claimed in claim 5, further comprising a solder layer formed over the second ceramic layer, wherein the material of the solder layer is tin or tin alloy.

8. The support substrate structure for supporting an electronic component thereon as claimed in claim 7, further comprising a heat dissipation component disposed on the solder layer, wherein the heat dissipation component connects to the second ceramic layer via the solder layer.

9. The support substrate structure for supporting an electronic component thereon as claimed in claim 7, further comprising a metal middle layer disposed between the solder layer and the second ceramic layer.

10. The support substrate structure for supporting an electronic component thereon as claimed in claim 9, wherein the material of the metal middle layer is chromium, copper, nickel, gold, silver or alloy thereof.

11. The support substrate structure for supporting an electronic component thereon as claimed in claim 1, wherein the insulating thermal conductive layer is a diamond-like carbon film or a diamond film.

12. The support substrate structure for supporting an electronic component thereon as claimed in claim 11, wherein the diamond-like carbon film has a dopant, and the dopant is fluorine, silicon, nitrogen, boron or a mixture thereof.

13. The support substrate structure for supporting an electronic component thereon as claimed in claim 12, wherein the amount of the fluorine or the silicon in the diamond-like carbon film is 1-40 atom % or 5-20 atom %.

14. The support substrate structure for supporting an electronic component thereon as claimed in claim 12, wherein the amount of the nitrogen or the boron in the diamond-like carbon film is 1-20 atom % or 5-10 atom %.

15. The support substrate structure for supporting an electronic component thereon as claimed in claim 1, wherein the thickness of the insulating thermal conductive layer is in a range of 0.1 to 30 μm or 2 to 3 μm.

16. The support substrate structure for supporting an electronic component thereon as claimed in claim 1, wherein the thickness of the conductive pattern is in a range of 0.1 to 100 μm or 20 to 40 μm.

17. A method for manufacturing a support substrate structure for supporting an electronic component thereon, comprising:
providing a thermal conductive substrate having an upper surface and a lower surface;
forming a first ceramic layer on the upper surface of the thermal conductive substrate;
forming an insulating thermal layer on the first ceramic layer;
forming a conductive layer on the insulating thermal conductive layer; and
removing a part of the conductive layer to form a conductive pattern on the insulating thermal conductive layer.

18. The method as claimed in claim 17, further comprising: forming a second ceramic layer on the lower surface of the thermal conductive substrate, wherein a method for forming the first ceramic layer and the second ceramic layer is an anodizing process or a thermal treatment process.

19. The method as claimed in claim 18, further comprising: forming a solder layer over the second ceramic layer.

20. The method as claimed in claim 19, further comprising: forming a metal middle layer between the solder layer and the second ceramic layer.

21. The method as claimed in claim 19, further comprising: providing a heat dissipation component on the solder layer, wherein the heat dissipation component connects to the second ceramic layer via the solder layer.

22. The method as claimed in claim 17, wherein the insulating thermal conductive layer is a diamond-like carbon film or a diamond film, the diamond-like carbon film has a dopant, and the dopant is fluorine, silicon, nitrogen, boron or a mixture thereof.

23. The method as claimed in claim 22, wherein the amount of the fluorine or the silicon in the diamond-like carbon film is 1-40 atom % or 5-20 atom %.

24. The method as claimed in claim 22, wherein the amount of the nitrogen or the boron in the diamond-like carbon film is 1-20 atom % or 5-10 atom %.

25. The method as claimed in claim 17, wherein a method for forming the insulating thermal conductive layer is chemical vapor deposition.

26. The method as claimed in claim 17, wherein a method for forming the conductive layer is sputtering, electroplating or electroless plating.

27. The method as claimed in claim 17, further comprising:
providing an adhesive layer on the conductive pattern, wherein the electronic component connects to the conductive pattern via the adhesive layer.
